(19) United States
(12) Patent Application Publication
(10) Pub. No.: US 2026/0322400 A1
(43) Pub. Date: Oct. 15, 2026

(54) DECODING METHOD, ENCODING METHOD, AND RELATED DEVICES

(71) Applicant: HUAWEI TECHNOLOGIES CO., LTD., Shenzhen (CN)

(72) Inventors: Ivan Vladimirovich KIRILLOV, Moscow (RU); Ilya Vasiliev, Moscow (RU); Denis Parkhomenko, Moscow (RU); Yurii Kolabushin, Moscow (RU); Kirill CHERNYSHEV, Moscow (RU); Andrey Sergeevich SHUTKIN, Moscow (RU); Alexander Andreevich PLETNEV, Moscow (RU); Dmitry Nikolaevich Babin, Moscow (RU); Alexey Kolosov, Moscow (RU)

(21) Appl. No.: 19/692,020

(22) Filed: May 29, 2026

Related U.S. Application Data
(63) Continuation of application No. PCT/RU2023/000377, filed on Nov. 30, 2023.

(51) Int. Cl. H03M 7/30; G06N 3/0455

(52) U.S. Cl. CPC H03M 7/3079; G06N 3/0455; H03M 7/6005; H03M 7/6011

(57) ABSTRACT

Embodiments of the present application provide a decoding method, an encoding method, and related device. The decoding method may include receiving an encoded signal and an encoded global feature. The decoding method may include deriving a reconstructed global semantics according to the encoded global feature by using a global decoding model. The decoding method may include deriving a predication information according to a series of decoded signals by using a prediction model. The decoding method may include deriving a context information corresponding to the encoded signal according to the reconstructed global semantics and the prediction information according to a context extraction model. The decoding method may include decoding the encoded signal according to the context information by using a signal decoding model.

### CROSS-REFERENCE TO RELATED APPLICATIONS

PCT/RU2023/000377, filed on Nov. 30, 2023, the disclosure of which is hereby incorporated by reference in its entirety.

This application is a continuation of International Application No.

### TECHNICAL FIELD

Embodiments of the present application relate to the field of signal processing technologies, and more specifically, related to a decoding method, an encoding method and related devices.

### BACKGROUND

Artificial intelligence (AI) is a rapidly growing field of technology that involves simulating human intelligence processes through machine learning, deep learning, natural language processing, computer vision, and other advanced techniques.

AI has been widely used in image signal processing, video signal processing, and audio signal processing. With the help of AI techniques, tasks such as image recognition, object detection, scene analysis, video analysis, speech recognition, and speech synthesis can be achieved. In the field of coding and decoding, AI has also made significant progress. For example, AI is widely used for compression, transcoding, adaptive bit rate control, quality analysis, and optimization. AI may enhance the efficiency and quality of coding and decoding processes.

Compared to conventional encoding and decoding methods, AI-based encoding and decoding is an emerging technology. As a result, there are still some issues that need to be addressed.

### SUMMARY

Embodiments of the present application provide a decoding method, an encoding method, and related device. The proposed technical solution offers the potential for enhanced decoding and encoding efficiency and quality.

According to a first aspect, an embodiment of the present application provides a decoding method. The decoding method may include receiving an encoded signal and an encoded global feature. The decoding method may include deriving a reconstructed global semantics according to the encoded global feature by using a global decoding model. The decoding method may include deriving a predication information according to a series of decoded signals by using a prediction model. The decoding method may include deriving a context information corresponding to the encoded signal according to the reconstructed global semantics and the prediction information according to a context extraction model. The decoding method may include decoding the encoded signal according to the context information by using a signal decoding model.

According to the aforementioned technical solution, a decoding device may obtain the encoded global feature from the encoding device. The encoded global feature is obtained according to a series of input signals. Based on the global feature, the decoding device may obtain a context information corresponding to the encoded signal. Further, the encoded signal may be obtained based on the context information. In other word, the context information may be used on both an encoding procedure and a corresponding decoding procedure. The context information may be enriched by the global feature extracted from the series of input signals. Therefore, decoding and encoding efficiency may be improved. Further, an encoding-decoding quality may also be improved. For example, when the technical solution used for video encoding/decoding, a good performance metric (e.g., peak signal-to-noise ratio bitrate distortion (PSNR-BD-rate) result, multi-scale structural similarity bitrate distortion (MS-SSIM-BD-rate), or the like) result may be obtained

Optionally, the number of signals inside the group may be fixed. Optionally, the number of the signals inside the group may be not fixed.

In a possible implementation of the first aspect, the context information includes N piece(s) of scale information, Nis a positive integer; the decoding the encoded signal according to the context information by using a signal decoding model, includes: decoding the encoded signal according to the N piece(s) of scale information by using the signal decoding model, wherein the signal decoding model includes at least N layer(s), each of the N piece(s) of scale information is an input of one of the at least N layer(s).

When the context information includes a plurality of pieces of scale information, different scale information may be injected in different layer of the signal decoding model, which may bring a better decoding result.

In a possible implementation of the first aspect, the decoding the encode signal according to the context information by using a signal decoding model, includes: decoding the encoded signal according to the context information to obtain a reconstructed feature of a target signal by using the signal decoding model; the method further includes: deriving a reconstructed target signal according to the reconstructed feature of the target signal by using a signal generating model.

Optionally, the encoded global feature may be derived according to a global semantics of a series of input signals. The global semantics of the series of input signals may be derived by using a global extraction model.

Optionally, the encoded signal may be obtained by performing an entropy coding operation on a latent representation of a target input signal, the latent representation of the target input signal may be derived according to a context information of a target signal by using a signal encoding operation.

Optionally, the context information of the target signal may be derived according to the reconstructed global semantics and a prediction information by using a context extraction model, the reconstructed global semantics may be obtained by decoding the encoded global feature by using a global decoding model, and the prediction information may be derived according to the series of decoded signals corresponding to the series of input signals by using a prediction mode.

Optionally, the encoded global feature may be obtained by performing an entropy coding operation on a global latent representation of the global semantics, the global latent representation of the global semantics may be derived by using a global encoding model.

Optionally, the global semantics of the series of input signals may be extracted from the series of input signals by using the global extraction model.

Optionally, the global semantics of the series of input signals may be extracted from a latent representation of the series of input signals by using the global extraction model.

Optionally, the global semantics of the series of input signals may be extracted from motion information of the series of input signals by using the global extraction model.

Optionally, when the context information of the target input signal includes the N piece(s) of scale information, the latent representation of the target input signal may be derived according to the N piece(s) of scale information by using the signal encoding model, where the signal encoding model comprises at least N layer(s), each of the N piece(s) of scale information is an input of one of the at least N layer(s).

Optionally, when the context information of the target input signal includes the N piece(s) of scale information, a temporal prior information may be derived according to the N piece(s) of scale information by using a temporal prior model, where the temporal prior model comprises at least N layer(s), each of the N piece(s) of scale information is an input of one of the at least N layer(s), and the entropy coding operation may be performed on the latent representation of the target input signal according to the temporal prior information to obtain the encoded signal.

Optionally, the encoded signal and the encoded global feature may be carried by a same bitstream.

Optionally, the encoded signal may be carried by a first bitstream, and the encoded global feature may be carried by a second bitstream. In other words, the encoded signal and the encoded global feature may be carried by different bitstreams.

Optionally, all of the above-mentioned models may be trained together.

According to a second aspect, an embodiment of the present application provides an encoding method. The encoding method may include deriving a global semantics of a series of input signals by using a global extraction model. The encoding method may include deriving an encoded global feature corresponding to the global semantics. The encoding method may include decoding the encoded global feature corresponding to the global semantics to obtain a reconstructed global semantics by using a global decoding model. The encoding method may include deriving a prediction information according to a series of decoded signals corresponding to the series of input signals by using a prediction model. The encoding method may include deriving a context information of the target input signal according to the reconstructed global semantics and the prediction information by using a context extraction model. The encoding method may include deriving a latent representation of the target input signal according to the context information by using a signal encoding model. The encoding method may include performing an entropy coding operation on the latent representation of the target input signal to obtain an encoded signal.

According to the aforementioned technical solution, the encoding device may determine the global feature and transmit the global feature to the decoding device. The global feature is obtained according to a group of input signals. Based on the global feature, both the encoding device and the decoding device may obtain a context information corresponding to the encoded signal. The encoded signal may be obtained based on the context information, and the decoding device may decode the encoded signal according to the context information. In other word, the context information may be used on both an encoding procedure and a corresponding decoding procedure. The context information may be enriched by the global feature extracted from the group of input signals. Therefore, decoding and encoding efficiency may be improved. Further, an encoding-decoding quality may also be improved. For example, when the technical solution used for video encoding/decoding, a good performance metric (e.g., peak signal-to-noise ratio bitrate distortion (PSNR-BD-rate) result, multi-scale structural similarity bitrate distortion (MS-SSIM-BD-rate), or the like) result may be obtained

Optionally, the number of signals inside the group may be fixed. Optionally, the number of the signals inside the group may be not fixed.

In a possible implementation of the second aspect, the deriving an encoded global feature corresponding to the global semantic, includes: deriving a global latent representation of the global semantics by using a global encoding model; performing the entropy coding operation on the global latent representation of the global semantics to obtain the encoded global feature corresponding to the global semantic.

Compared with the global semantics, the global latent representation may helps reduce a dimensionality of the global semantics obtained from the group of input signals. Correspondingly, storage and computational costs of the global latent representation may be smaller than the original data, that is, the global semantics.

In a possible implementation of the second aspect, the deriving, by an encoding device, a global semantics of a series of input signals by using a global extraction model, includes: extracting the global semantics of the series of input signals from the series of input signals by using the global extraction model.

In a possible implementation of the second aspect, the deriving, by an encoding device, a global semantics of a series of input signals by using a global extraction model, includes: deriving a latent representation of the series of input signals; extracting the global semantics of the series of input signals from the latent representation of the series of input signals by using the global extraction model.

In a possible implementation of the second aspect, the deriving, by an encoding device, a global semantics of a series of input signals by using a global extraction model, includes: deriving motion information of the series of input signals; extracting the global semantics of the series of input signals from the motion information of the series of input signals by using the global extraction model.

In a possible implementation of the second aspect, the context information of the target input signal includes N piece(s) of scale information, N is a positive integer; the deriving a latent representation of the target input signal according to the context information by using a signal encoding model, includes: deriving a latent representation of the target input signal according to the N piece(s) of scale information by using the signal encoding model, wherein the signal encoding model includes at least N layer(s), each of the N piece(s) of scale information is an input of one of the at least N layer(s).

When the context information includes a plurality of pieces of scale information, different scale information may be injected in different layer of the signal encoding model, which may bring a better encoding result.

In a possible implementation of the second aspect, the method further includes: deriving a temporal prior information according to the N piece(s) of scale information by using a temporal prior model, wherein the temporal prior model includes at least N layer(s), each of the N piece(s) of scale information is an input of one of the at least N layer(s); the performing an entropy coding operation on the latent representation of the target input signal to obtain an encoded signal, includes: performing the entropy coding operation on the latent representation of the target input signal according to the temporal prior information to obtain the encoded signal.

Based on the above-mentioned technical solution, the entropy encoding operation is also based on the enriched context information. Therefore, the efficiency and quality of the encoding and decoding may be further improved.

In a possible implementation of the second aspect, the method further includes: transmitting the encoded signal and the encoded global feature corresponding to the global semantics.

Optionally, all of the above-mentioned models may be trained together.

According to a third aspect, an embodiment of the present application provides an electronic device, and the electronic device has a function of implementing the method in the first aspect. The function may be implemented by hardware, or may be implemented by hardware executing corresponding software. The hardware of the software includes one or more units corresponding to the function.

According to a fourth aspect, an embodiment of the present application provides an electronic device, and the electronic device has a function of implementing the method in the second aspect. The function may be implemented by hardware, or may be implemented by hardware executing corresponding software. The hardware of the software includes one or more units corresponding to the function.

According to a fifth aspect, an embodiment of the present application provides a computer readable storage medium including instructions. When the instructions run on an electronic device, the electronic device is enabled to perform the method in the first aspect or any possible implementation of the first aspect.

According to a sixth aspect, an embodiment of the present application provides a computer readable storage medium including instructions. When the instructions run on an electronic device, the electronic device is enabled to perform the method in the second aspect or any possible implementation of the second aspect.

According to a seventh aspect, an embodiment of the present application provides a computer readable storage medium including instructions. When the instructions run on an electronic device, the electronic device is enabled to perform the method in the third aspect or any possible implementation of the second aspect.

According to an eighth aspect, an embodiment of the present application provides an electronic device, including a processor and a memory. The processor is connected to the memory. The memory is configured to store instructions, and the processor is configured to execute the instructions. When the processor executes the instructions stored in the memory, the processor is enabled to perform the method in the first aspect or any possible implementation of the first aspect.

According to a ninth aspect, an embodiment of the present application provides an electronic device, including a processor and a memory. The processor is connected to the memory. The memory is configured to store instructions, and the processor is configured to execute the instructions. When the processor executes the instructions stored in the memory, the processor is enabled to perform the method in the second aspect or any possible implementation of the second aspect.

According to a tenth aspect, an embodiment of the present application provides a chip system, where the chip system includes a memory and a processor, and the memory is configured to store a computer program, and the processor is configured to invoke the computer program from the memory and run the computer program, so that an electronic device on which the chip system is disposed performs the method in the first aspect or any possible implementation of the first aspect.

According to an eleventh aspect, an embodiment of the present application provides a chip system, where the chip system includes a memory and a processor, and the memory is configured to store a computer program, and the processor is configured to invoke the computer program from the memory and run the computer program, so that an electronic device on which the chip system is disposed performs the method in the second aspect or any possible implementation of the second aspect.

According to a twelfth aspect, an embodiment of the present application provides a computer program product, where when the computer program product runs on an electronic device, the electronic device is enabled to perform the method in the first aspect or any possible implementation of the first aspect.

According to a thirteenth aspect, an embodiment of the present application provides a computer program product, where when the computer program product runs on an electronic device, the electronic device is enabled to perform the method in the second aspect or any possible implementation of the second aspect.

According to a fourteenth aspect, an embodiment of the present application provides computer readable storage medium, where the computer readable storage medium stores a bitstream, the bitstream is obtained by using the method according to the second aspect or any possible implementation of the second aspect.

### DESCRIPTION OF DRAWINGS

FIG. 1 is a schematic block diagram illustrating a coding system according to some embodiments of the present application.

FIG. 2 illustrates an encoding method provided by some embodiments of the present application.

FIG. 3 is an example of the neural network including Conv3D layers.

FIG. 4 illustrates a U-net convolution network according to some embodiments of the present application.

FIG. 5 illustrates another U-net convolution network according to some embodiments of the present application.

FIG. 6 illustrates a block diagram of a transformer according to some embodiments of the present application.

FIG. 7 illustrates a global encoding model according to some embodiments of the present application.

FIG. 8 illustrates the global decoding model according to some embodiments of the present application.

FIG. 9 illustrates a context extraction model and a signal encoding model according to some embodiments of the present application.

FIG. 10 illustrates a decoding method according to some embodiments of the present application.

FIG. 11 is a schematic block diagram of an electronic device according to some embodiments of the present application.

FIG. 12 is a schematic block diagram of an electronic device according to some embodiments of the present application.

FIG. 13 is a schematic block diagram of an electronic device according to some embodiments of the present application.

FIG. 14 is a schematic block diagram of a system architecture according to some embodiments of the present application.

### DESCRIPTION OF EMBODIMENTS

The following describes the technical solutions in the present application with reference to the accompanying drawings.

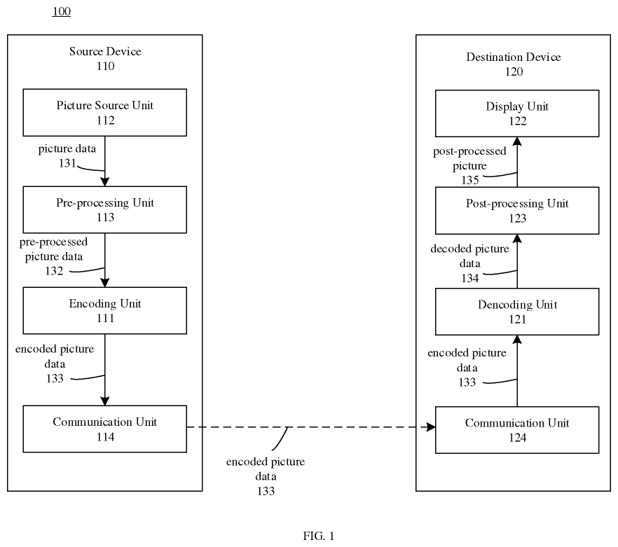

FIG. 1 is a schematic block diagram illustrating a coding system according to some embodiments of the present application. Referring to FIG. 1, the coding system 100 includes a source device 110 configured to provide encoded picture data to a destination device 120 for decoding the encoded picture data. For convenience, it is assumed that the coding system 100 is a picture coding system. As will be apparent for the skilled person, the picture coding system is just example embodiments of the invention and embodiments of the invention are not limited thereto.

The source device 110 may include an encoding unit 111. Optionally, the source device 110 may further include a picture source unit 112, a pre-processing unit 113, and a communication unit 114.

The picture source unit 112 may include or be any kind of picture capturing device, for example for capturing a rea-word picture, and/or any kind of a picture generating device, for example a computer-graphics processor for generating a computer animated picture, or any kind of device for obtaining and/or providing a real-word picture, a computer animated picture (e.g., a screen content, a virtual reality (VR) picture) and/or any combination thereof (e.g., an augmented reality (AR) picture). In the following, all these kinds of pictures and any other kind of picture will be referred to as “picture”.

A (digital) picture is or can be regarded as a two-dimensional array or matrix of samples with intensity values. A sample in the array may also be referred to as pixel (short form of picture element) or a pel. The number of samples in horizontal and vertical direction (or axis) of the array or picture define the size and/or resolution of the picture. For representation of color, typically three-color components are employed, i.e. the picture may be represented or include three sample arrays. In RBG format or color space a picture comprises a corresponding red, green and blue sample array. However, in video coding each pixel is typically represented in a luminance/chrominance format or color space, e.g. YCbCr, which comprises a luminance component indicated by Y (sometimes also L is used instead) and two chrominance components indicated by Cb and Cr. The luminance (or short luma) component Y represents the brightness or grey level intensity (e.g. like in a grey-scale picture), while the two chrominance (or short chroma) components Cb and Cr represent the chromaticity or color information components. Accordingly, a picture in YCbCr format comprises a luminance sample array of luminance sample values (Y), and two chrominance sample arrays of chrominance values (Cb and Cr). Pictures in RGB format may be converted or transformed into YCbCr format and vice versa, the process is also known as color transformation or conversion. If a picture is monochrome, the picture may comprise only a luminance sample array.

The picture source unit 112 may be, for example a camera for capturing a picture, a memory, e.g. a picture memory, comprising or storing a previously captured or generated picture, and/or any kind of interface (internal or external) to obtain or receive a picture. The camera may be, for example, a local or integrated camera integrated in the source device, the memory may be a local or integrated memory, e.g. integrated in the source device. The interface may be, for example, an external interface to receive a picture from an external video source, for example an external picture capturing device like a camera, an external memory, or an external picture generating device, for example an external computer-graphics processor, computer or server. The interface can be any kind of interface, e.g. a wired or wireless interface, an optical interface, according to any proprietary or standardized interface protocol. The interface for obtaining the picture data 312 may be the same interface as or a part of the Communication unit 114.

In distinction to the pre-processing unit 113 and the processing performed by the pre-processing unit 113, the picture or picture data 131 may also be referred to as raw picture or raw picture data 131.

The pre-processing unit 113 is configured to receive the (raw) picture data 131 and to perform pre-processing on the picture data 131 to obtain a pre-processed picture 132 or pre-processed picture data.

The pre-processing performed by the pre-processing unit 113 may, e.g., comprise trimming, color format conversion (e.g. from RGB to YCbCr), color correction, or de-noising. The encoding unit 111 is configured to receive the pre-processed picture data 132 and provide encoded picture data 133.

The communication unit 114 of the source device 110 may be configured to receive the encoded picture data 133 and to directly transmit it to another device, e.g. the destination device 120 or any other device, for storage or direct reconstruction, or to process the encoded picture data 133 for respectively before storing the encoded picture data 133 and/or transmitting the encoded picture data 133 to another device, e.g. the destination device 120 or any other device for decoding or storing.

The destination device 120 comprises a decoding unit 121, and may additionally, i.e. optionally, comprise a communication unit 124, a post-processing unit 123 and a display unit 122.

The communication unit 124 of the destination device 120 is configured receive the encoded picture data 133, e.g. directly from the source device 110 or from any other source, e.g. a memory, e.g. an encoded picture data memory.

The communication unit 114 and the communication unit 124 may be configured to transmit respectively receive the encoded picture data 133 via a direct communication link between the source device 110 and the destination device 120, e.g. a direct wired or wireless connection, or via any kind of network, e.g. a wired or wireless network or any combination thereof, or any kind of private and public network, or any kind of combination thereof.

The communication unit 114 may be, e.g., configured to package the encoded picture data 133 into an appropriate format, e.g. packets, for transmission over a communication link or communication network, and may further comprise data loss protection and data loss recovery.

The communication unit 124, forming the counterpart of the communication unit 114, may be, e.g., configured to de-package the packets to obtain the encoded picture data 133 and may further be configured to perform data loss protection and data loss recovery, e.g. comprising error concealment.

The communication unit 124, forming the counterpart of the communication unit 114, may further be configured to perform communication without or with limited data loss protection, and without re-transmission of lost of corrupted data to minimize communication delay and end-to-end latency between source and destination device. In such configuration the encoded picture data 133 may contain errors after receiving by communication unit 124. For binary represented signals the communication errors will lead to inverting 0 to 1 and vice versa.

Both, the communication unit 114 and the communication unit 124 may be configured as unidirectional communication interfaces as indicated by the arrow for the encoded picture data 133 in FIG. 1 pointing from the source device 110 to the destination device 120, or bi-directional

The communication units, and may be configured, e.g. to send and receive messages, e.g. to set up a connection, to acknowledge and/or re-send lost or delayed data including picture data, and exchange any other information related to the communication link and/or data transmission, e.g. encoded picture data transmission.

The decoding unit 121 is configured to receive the encoded picture data 133 and provide decoded picture data 134.

The post-processing unit 123 of destination device 120 is configured to post-process the decoded picture data 134 to obtain post-processed picture data 135. The post-processing performed by the post-processing unit 123 may comprise, e.g. color format conversion (e.g. from YCbCr to RGB), color correction, trimming, or re-sampling, or any other processing, e.g. for preparing the decoded picture data 134 for display, e.g. by display unit 122.

The display unit 122 of the destination device 120 is configured to receive the post-processed picture data 135 for displaying the picture, e.g. to a user or viewer. The display unit 122 may be or comprise any kind of display for representing the reconstructed picture, e.g. an integrated or external display or monitor. The displays may, e.g. comprise cathode ray tubes (CRT), liquid crystal displays (LCD), plasma displays, organic light emitting diodes (OLED) displays or any kind of other display, such as beamer, hologram (3D), or the like.

Although FIG. 1 depicts the source device 110 and the destination device 120 as separate devices, embodiments of devices may also comprise both or both functionalities, the source device 110 or corresponding functionality and the destination device 120 or corresponding functionality. In such embodiments the source device 110 or corresponding functionality and the destination device 120 or corresponding functionality may be implemented using the same hardware and/or software or by separate hardware and/or software or any combination thereof.

As will be apparent for the skilled person based on the description, the existence and (exact) split of functionalities of the different units or functionalities within the source device 110 and/or destination device 120 as shown in FIG. 1 may vary depending on the actual device and application.

Therefore, the source device 110 and the destination device 120 as shown in FIG. 1 are just example embodiments of the invention and embodiments of the invention are not limited to those shown in FIG. 1.

The source device 110 and the destination device 120 may comprise any of a wide range of devices, including any kind of handheld or stationary devices, e.g. notebook or laptop computers, mobile phones, smart phones, tablets or tablet computers, cameras, desktop computers, set-top boxes, televisions, display devices, digital media players, video gaming consoles, video streaming devices, broadcast receiver device, or the like and may use no or any kind of operating system.

The embodiments of this application relate to application of a large quantity of neural networks. Therefore, for ease of understanding, related terms and related concepts such as the neural network in the embodiments of this application are first described below.

### (1) Neural Network (NN)

The neural network may include neurons. The neuron may be an operation unit that uses xₛ and an intercept 1 as inputs, and an output of the operation unit may be as follows:

$${h}_{W , b} ( x ) = f ( {W}^{T} x ) = f ( {\sum }_{s = 1}^{n} {W}_{s} {x}_{s} + b )$$

Herein, s=1, 2, . . . , or n, n is a natural number greater than 1, Ws is a weight of xs, and b is bias of the neuron. f is an activation function of the neuron, and the activation function is used to introduce a non-linear feature into the neural network, to convert an input signal in the neuron into an output signal. The output signal of the activation function may be used as an input of a next convolutional layer. The activation function may be a sigmoid function. The neural network is a network formed by connecting many single neurons together. To be specific, an output of a neuron may be an input of another neuron. An input of each neuron may be connected to a local receptive field of a previous layer to extract a feature of the local receptive field. The local receptive field may be a region including several neurons.

### (2) Deep Neural Network

The deep neural network (DNN), also referred to as a multi-layer neural network, may be understood as a neural network having many hidden layers. The “many” herein does not have a special measurement standard. The DNN is divided based on locations of different layers, and a neural network in the DNN may be divided into three types: an input layer, a hidden layer, and an output layer. Generally, the first layer is the input layer, the last layer is the output layer, and the middle layer is the hidden layer. Layers are fully connected. To be specific, any neuron at the ith layer is certainly connected to any neuron at the (i+1)th layer. Although the DNN looks to be complex, the DNN is actually not complex in terms of work at each layer, and is simply expressed as the following linear relationship expression: y̅=α(Wx̅+\vec{b}), where x̅ is an input vector, y̅ is an output vector, \vec{b} is a bias vector, W is a weight matrix (also referred to as a coefficient), and α( ) is an activation function. At each layer, the output vector y̅ is obtained by performing such a simple operation on the input vector x̅. Because there are many layers in the DNN, there are also many coefficients W and bias vectors \vec{b}. Definitions of these parameters in the DNN are as follows: The coefficient W is used as an example. It is assumed that in a DNN having three layers, a linear coefficient from the fourth neuron at the second layer to the second neuron at the third layer is defined as

$${w}_{24}^{3} .$$

The superscript 3 represents a layer at which the coefficient W is located, and the subscript corresponds to an output third-layer index 2 and an input second-layer index 4. In conclusion, a coefficient from the k^{th} neuron at the (L−1)^{th} layer to the j^{th} neuron at the Lth layer is defined as

$${W}_{jk}^{L} .$$

It should be noted that there is no parameter W at the input layer. In the deep neural network, more hidden layers make the network more capable of describing a complex case in the real world.

Theoretically, a model with a larger quantity of parameters indicates higher complexity and a larger “capacity”, and indicates that the model can complete a more complex learning task. Training the deep neural network is a process of learning a weight matrix, and a final objective of the training is to obtain a weight matrix of all layers of the trained deep neural network (a weight matrix including vectors W at many layers).

### (3) Convolutional Neural Network

The convolutional neural network (CNN) is a deep neural network having a convolutional structure. The convolutional neural network includes a feature extractor including a convolutional layer and an optional sub sampling layer. The feature extractor may be considered as a filter. A convolution process may be considered as using a trainable filter to perform convolution on an input image or a convolutional feature plane (feature map). The convolutional layer is a neuron layer that is in the convolutional neural network and at which convolution processing is performed on an input signal. At the convolutional layer of the convolutional neural network, one neuron may be connected only to some adjacent-layer neurons. A convolutional layer usually includes a plurality of feature planes, and each feature plane may include some neurons arranged in a rectangular form. Neurons in a same feature plane share a weight. The shared weight herein is a convolution kernel. Weight sharing may be understood as that an image information extraction manner is irrelevant to a location. A principle implied herein is that statistical information of a part of an image is the same as that of another part. This means that image information learned in a part can also be used in another part. Therefore, image information obtained through same learning can be used for all locations in the image. At a same convolutional layer, a plurality of convolution kernels may be used to extract different image information. Usually, a larger quantity of convolution kernels indicates richer image information reflected by a convolution operation.

The convolution kernel may be initialized in a form of a random-size matrix. In a process of training the convolutional neural network, the convolution kernel may obtain an appropriate weight through learning. In addition, a direct benefit brought by weight sharing is that connections between layers of the convolutional neural network are reduced and an overfitting risk is lowered.

### (4) Recurrent Neural Network

A recurrent neural network (RNN) is used to process sequence data. In a conventional neural network model, from an input layer to a hidden layer and then to an output layer, the layers are fully connected, and nodes at each layer are not connected. Such a common neural network resolves many difficult problems, but is still incapable of resolving many other problems. For example, if a word in a sentence is to be predicted, a previous word usually needs to be used, because adjacent words in the sentence are not independent. A reason why the RNN is referred to as the recurrent neural network is that a current output of a sequence is also related to a previous output of the sequence. A specific representation form is that the network memorizes previous information and applies the previous information to calculation of the current output. To be specific, nodes at the hidden layer are connected, and an input of the hidden layer not only includes an output of the input layer, but also includes an output of the hidden layer at a previous moment. Theoretically, the RNN can process sequence data of any length. Training for the RNN is the same as training for a conventional CNN or DNN. An error back propagation algorithm is also used, but there is a difference: If the RNN is expanded, a parameter such as W of the RNN is shared. This is different from the conventional neural network described in the foregoing example. In addition, during use of a gradient descent algorithm, an output in each step depends not only on a network in the current step, but also on a network status in several previous steps. The learning algorithm is referred to as a back propagation through time (BPTT) algorithm.

Now that there is a convolutional neural network, why is the recurrent neural network required? A reason is simple. In the convolutional neural network, it is assumed that elements are independent of each other, and an input and an output are also independent, such as a cat and a dog. However, in the real world, many elements are interconnected. For example, stocks change with time. For another example, a person says: I like traveling, and my favorite place is Yunnan. I will go if there is a chance. If there is bank filling, people should know that “Yunnan” will be filled in the blank. A reason is that the people can deduce the answer based on content of the context. However, how can a machine do this? The RNN emerges. The RNN is intended to make the machine capable of memorizing like a human. Therefore, an output of the RNN needs to depend on current input information and historical memorized information.

### (5) Loss Function

In a process of training the deep neural network, because it is expected that an output of the deep neural network is as much as possible close to a predicted value that is actually expected, a predicted value of a current network and a target value that is actually expected may be compared, and then a weight vector of each layer of the neural network is updated based on a difference between the predicted value and the target value (certainly, there is usually an initialization process before the first update, to be specific, parameters are preconfigured for all layers of the deep neural network). For example, if the predicted value of the network is large, the weight vector is adjusted to decrease the predicted value, and adjustment is continuously performed until the deep neural network can predict the target value that is actually expected or a value that is very close to the target value that is actually expected. Therefore, “how to obtain, through comparison, a difference between a predicted value and a target value” needs to be predefined. This is the loss function or an objective function. The loss function and the objective function are important equations used to measure the difference between the predicted value and the target value. The loss function is used as an example. A higher output value (loss) of the loss function indicates a larger difference. Therefore, training of the deep neural network is a process of minimizing the loss as much as possible.

### (6) Transformer

A transformer is a deep learning architecture that relies on the parallel multi-head attention mechanism. The transformer includes two main components: an encoder and a decoder. The encoder may include encoding layers that sequentially process the input tokens, and similarly, the decoder may include decoding layers that iteratively process the encoder's output and the decoder's generated tokens. Each encoder layer is responsible for producing contextualized representations of the tokens. These representations capture information from other input tokens through the self-attention mechanism. In other words, each representation combines information from different input tokens to create a comprehensive understanding. On the other hand, each decoder layer contains two attention sublayers. The first sublayer, called cross-attention, incorporates the contextualized representations generated by the encoder. It enables the decoder to leverage the knowledge learned from the input tokens during the generation of output tokens. The second sublayer, known as self-attention, facilitates the integration of information among the input tokens within the decoder. This self-attention mechanism allows the decoder to consider the tokens that have already been generated, enabling it to automatically learn which tokens are important and need to be predicted accurately. In other words, through self-attention, the decoder can attend to and analyze the previously generated tokens during the sequence generation process, enhancing its understanding of context and making more precise predictions. To further enhance the processing of outputs, both the encoder and decoder layers include a feed-forward neural network. This network performs additional computations on the outputs. Additionally, residual connections and layer normalization steps are applied in both the encoder and decoder layers to improve the model's stability and performance. The transformer has found widespread applications in natural language processing (NLP) and computer vision tasks, including machine translation, text classification, image classification, speech recognition, and more.

### (7) Deep Learning Based Intra Prediction:

In the traditional intra prediction, the neighboring reconstructed samples of a coding block are used to get the prediction of the samples inside the coding block along a specific straight direction (or some fixed pattern) which is indicated by an intra prediction mode. With the deep learning with the reference samples, the generated prediction sample value could be more flexible, and could be more similar with the samples inside the current coding block.

### (8) Deep Learning Based Inter Prediction

In the traditional inter prediction, the reference block in a reference picture are used to get the prediction of the samples inside the current coding block, by using a simple weighting method. By using deep learning with the reference blocks, more flexible predictions can be obtained, which could be more similar with the samples inside the current coding block.

### (9) Deep Learning Based Entropy Coding

In the traditional entropy coding, some neighboring information or priori knowledge are used as context, which will be used to estimate the probability of a syntax value for arithmetic coding. By using deep learning with context, more accurate probability could be estimated.

The present application provides an encoding method and a decoding method. According to the encoding method, the encoding device may obtain a context information according to a series of input signals by using a neural network and encoding a target input signal according to the context information. Correspondingly, the decoding device may obtain the encoded signal and decodes the obtained encoded signal according to the context information. In some embodiments, an input signal belonging to the series of input signals may be referred to as a reference signal. Correspondingly, the series of input signals may be referred to as a series of reference signals.

The series of input signals may include two or more input signals. In some embodiments, the two or more input signals may be previous input signals of the target input signal. In some other embodiments, the two or more input signals maybe future signals of the target input signal. In some other embodiments, some of the two or more input signals may be previous input signals, while other signals may be further signals.

The embodiments provided by the present application may be used to encode a video frame, an image, an audio frame, or the like, and the present application is not limited thereto. For example, when the present application is used to encoding the video frame, the input signal may be a video frame, and the series of input signals may include a group of video frames. When the present application is used to encoding the audio frame, the input signal may be an audio frame, and the series of input signals may include a group of audio frame.

For convenience, in the following embodiments, it is assumed that the input signal is a video frame. In some embodiments, the video frame may also be referred to “frame”, while the reference signal may be referred to “reference frame”.

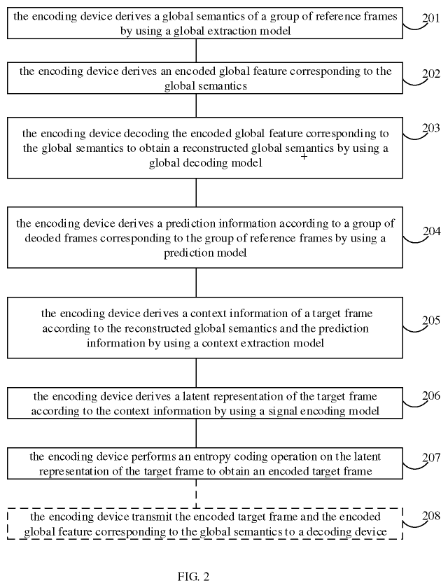

FIG. 2 illustrates an encoding method provided by some embodiments of the present application. For convenience, it is assumed that the operation illustrated in FIG. 2 is performed by an encoder or an encoding device. In some embodiments, the encoder or the encoding device may be a terminal device (e.g., a personal computer, a laptop, a mobile phone, a tablet computer, an augmented reality (AR)/virtual reality (VR) terminal, or the like), a server, a network device or the like. In some other embodiments, the encoder or the encoding device may be a component in the terminal, the server, the network device or the like. For example, the encoder or the encoding device may be a chip, a system on chip (SoC), a circuit, and so on.

201, the encoding device derives a global semantics of a group of reference frames by using a global extraction model.

The global extraction model, also referred to as a global extractor, is configured to extract the global semantics of the group of reference frames.

In some embodiments, the global extraction model may directly extract the global semantics from the group of reference frames. For these embodiments, the encoding device may extract the global semantics of the group of reference frames from the group of the reference frames by using the global extraction model.

In some other embodiments, the global extraction model may extract the global semantics from a latent representation of the group of the reference frames. Under this condition, the encoding device may obtain the latent representation of the group of the reference frames. Then the encoding device may extract the global semantics of the group of reference frames from the latent representation of the group of reference frames by using the global extraction model.

In some embodiments, the encoding device may perform an analysis transform on each of the group of reference frames. A result of the analysis transform is a latent representation. Therefore, the encoding device may obtain a group of latent representations, each of the group of latent representations corresponds one of group of reference frames, and each of the group of latent representations is an analysis transform result of the corresponding reference frame. The group of latent representations may be referred to as the latent representation of the group of reference frames.

In some other embodiments, the global extraction model may extract the global semantics from motion information of the group of reference frames. For these embodiments, the encoding device may obtain the motion information of the group of reference frames. Then the encoding device may extract the global semantics from the motion information of the group of reference frames by using the global extraction model.

For example, in some embodiments, the motion information may include at least one: estimated motion flow between pairs of frames, estimated points trajectories on the whole group of reference frames, motion vectors, or the like. The estimated motion flow between pairs of frames include information about displacement of each pixel from frame to frame. The estimated motion flow between pairs of frames may be estimated with a NN-based method (e.g., recurrent all-pairs field transforms (RAFT)), or some classic methods. The points trajectories reflect trajectories of one or more points during the whole group of reference frames. The points trajectories may be obtained by using a transformer network called CoTracker.

In some embodiments, the global extraction model is a neural network including 3D convolutional (Conv3d) layer. In some embodiments, the neural network may be a DNN, an CNN, or the like.

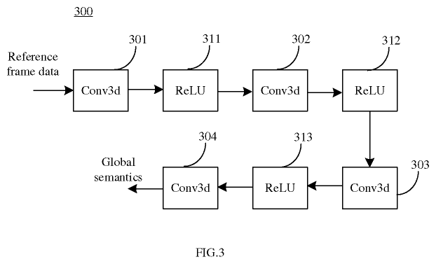

FIG. 3 illustrates the neural network including Conv3d layers.

The neural network 300 includes four Conv3d layers, that is, a Cov3d layer 301, a Conv3d layer 302, a Conv3d layer 303, and a Conv3d layer 304. The neural network 300 further includes three rectified linear units (ReLUs), that is, a ReLU 311, a ReLU 312, and a ReLU 313. A ReLU activation function is an activation function defined as a positive part of its argument. In other words, for input values greater than zero, the ReLU activation function keeps them unchanged; whereas for input values less than or equal to zero, the ReLU activation sets them to zero. In essence, the ReLU activation function retains the positive values and sets the negative values to zero. Mathematically, the ReLU action function may be defined as:

$$f ( x ) = {x}^{+} = max ( 0 , x ) = \frac{x + \vert x \vert}{2} = \{ \begin{matrix}x & if x > 0 \\ 0 & otherwise\end{matrix} , \qquad ( 1.1 )$$

$${f}^{′} ( x ) = \{ \begin{matrix}1 & if x > 0 \\ 0 & if x < 0\end{matrix} , \qquad ( 1.2 )$$

As previously mentioned, the global semantics may be extract from any one of the group of the reference frames, the latent representation of the group of reference frames, or the motion information of the group of reference frames. Therefore, the reference frame data illustrated in FIG. 3 may be one of the group of the reference frames, the latent representation of the group of reference frames, or the motion information of the group of reference frames. For convenience, it is assumed that the group of reference frames includes 8 reference frames, and the reference frame data (that is, an input of the neural network 300) is the latent representation of the group of reference frames. It is assumed that the shape of the latent representation of each of the 8 reference frames is [B, 8, 64, H/8, W/8], where B represents a batch size, H represents a height of the reference frame, and M represents a width of the reference frame.

Assuming parameters for the four Conv3d layers of the neural network 300 are shown in Table 1.

TABLE 1

| | input | output | Kernel | | |
|---|---|---|---|---|---|
| Conv3d | channels | channels | size | Stride | Padding |
| 301 | 64 | 128 | (3, 3, 3) | (2, 1, 1) | (1, 1, 1) |
| 302 | 128 | 128 | (3, 3, 3) | (2, 1, 1) | (1, 1, 1) |
| 303 | 128 | 128 | (3, 3, 3) | (2, 1, 1) | (1, 1, 1) |
| 304 | 128 | 128 | (3, 3, 3) | (2, 1, 1) | (1, 1, 1) |

Then a shape of an output of the neural network (that is, the global semantics determined according to the neural work 300) is [B, 64, H/8, W/8], where B represents the batch size, H represents the height of the reference frame, and W represents the width of the reference frame.

FIG. 3 is an example of the neural network including Conv3D layers. In some embodiments, the neural network may including less or more Conv3D layers and/or ReLU. In some other embodiments, the neural network may further include some other layers, e.g., one or more full connection layers, one or more pooling layers, or the like.

In some embodiments, the global extraction model may be a U-net convolution network.

FIG. 4 illustrates a U-net convolution network.

FIG. 4 depicts a U-net convolution network 400. Each box illustrated in FIG. 4 corresponds to a multi-channel feature map, and the number of channels of the feature map is denoted on top of the box. The x-y-size is provided at the lower left edge of the box. Boxes with shadow represents copied feature maps. The arrows denote different operations.

Similarly, input of the U-net convolution network 400 may be one of the followings the group of the reference frames, the latent representation of the group of reference frames, or the motion information of the group of reference frames. Output of the U-net convolution network 400 may be the global semantics.

In some embodiments, in order to reduce channel dimensionality of the input of the U-net convolution network an additional convolutional layer may be added prior to the U-net convolution network. Similarly, an additional convolutional layer may be added to reduce the channel dimensionality of the output of the U-new convolutional network.

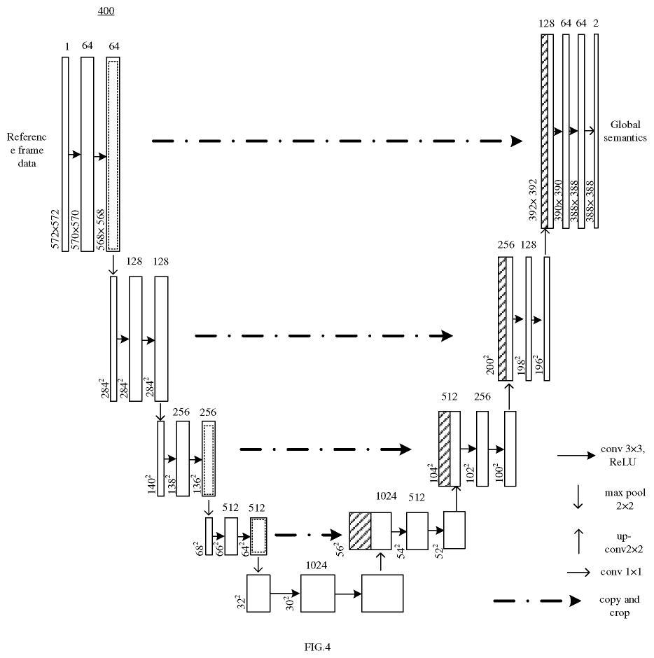

FIG. 5 illustrates another U-net convolution network according to some embodiments of the present application.

Referring to FIG. 5, the U-net convolutional network 500 includes a U-net convolution network module 501, a first convolutional layer 502, and a second convolutional layer 503. The U-net convolution network 501 may be the U-net convolution network 400 illustrated in FIG. 4.

In some other embodiments, the global extraction model may be a transformer.

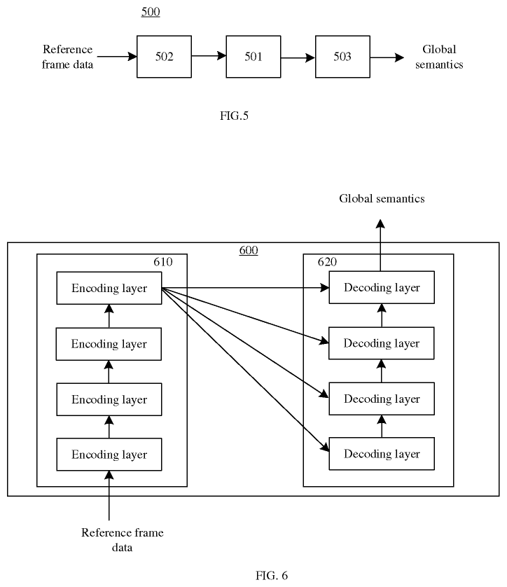

FIG. 6 illustrates a block diagram of a transformer.

Referring to FIG. 6, the transformer 600 includes an encoder 601 and a decoder 602. The encoder 601 includes several encoding layers, and the decoder 602 includes several decoding layers. Similarly, input of the transformer 600 may be one of the followings the group of the reference frames, the latent representation of the group of reference frames, or the motion information of the group of reference frames. Output of the transformer 600 may be the global semantics.

202, the encoding device derives an encoded global feature corresponding to the global semantics.

In some embodiments, the encoding device may perfume an entropy coding on global semantics to obtain the encoded global feature.

In some other embodiments, the encoding device may determine a global latent representation of the global semantics. Then the encoding device may perform the entropy coding on the global latent representation of the global semantics, and a result of the entropy coding is the encoded global feature. In other words, the encoded global feature is an encoded global latent representation. Transforming the global semantics into a latent representation may transform more complex form into a simple representation, which may improve efficiency of data process. For instance, it may reduce computation complexity and lower computational cost.

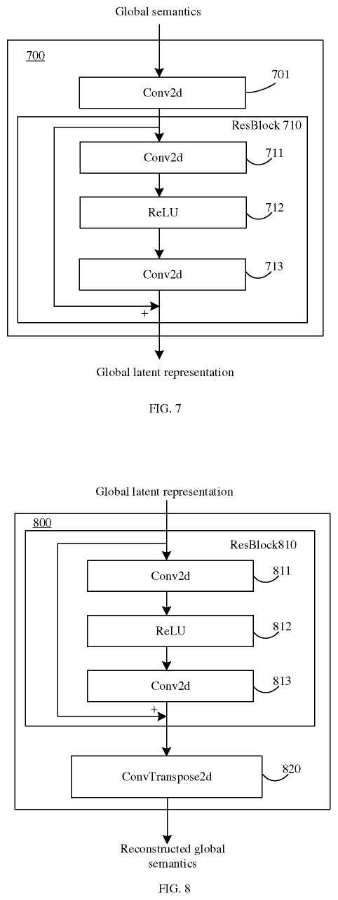

FIG. 7 illustrates a global encoding model. The encoding device may deriving the global representation of the global semantics by using the global encoding model.

Referring to FIG. 7, the global encoding model 700 includes a 2D convolutional (Conv2d) layer 701 and a ResBlock 710. The ResBlock 710 includes a Conv2d layer 711, a ReLU 712, and a Conv2d layer 713.

Assuming the shape of the global semantics is [B, 64, H/8, W/8], and assuming parameters for the three Conv2d layers of the global encoding model 700 are shown in Table 2.

TABLE 2

| Conv2d | input channels | output channels | Kernel size | Stride | Padding |
|---|---|---|---|---|---|
| 701 | 64 | 64 | (3, 3) | (2, 2) | (1, 1) |
| 711 | 64 | 64 | (3, 3) | (2, 2) | (1, 1) |
| 713 | 64 | 64 | (3, 3) | (2, 2) | (1, 1) |

Then a shape of the global latent representation is [B, 64, H/64, W/64], where B represents the batch size, H represents the height of the reference frame, and W represents the width of the reference frame.

In some embodiments, the global encoding model 700 may be referred to as a downsample block.

203, the encoding device decoding the encoded global feature corresponding to the global semantics to obtain a reconstructed global semantics by using a global decoding model.

FIG. 8 illustrates the global decoding model.

Referring to FIG. 8, the global decoding model 800 includes a ResBlock 810 and a 2D convolutional transpose (ConvTranspose2d) layer 820, where the ResBlock 810 includes a Conv2D layer 811, a ReLU 812, and a Conv2d layer 813.

Assuming the shape of the global semantics is [B, 64, H/8, W/8], and assuming parameters for the two Conv2d layers of the global encoding model 800 are shown in Table 3.

TABLE 3

| Conv2d | input channels | output channels | Kernel size | Stride | Padding |
|---|---|---|---|---|---|
| 811 | 64 | 64 | (3, 3) | (2, 2) | (1, 1) |
| 813 | 64 | 64 | (3, 3) | (2, 2) | (1, 1) |

Further, assuming the ConvTranspose2d layer 820 includes the following parameters: 64 input channels, 64 output channels, kernel size (3,3), stride (2,2), padding (1,1), and output padding (1,1). Then, a shape of the reconstructed global semantics may be [B, 64, H/8, W/8].

In some embodiments, the global decoding model 800 may be referred to as an upsample block.

204, the encoding device derives a prediction information according to a group of decoded frames corresponding to the group of reference frames by using a prediction model.

The group of decoded frames corresponds to a group of encoded frames obtained by the group of reference frames by using the encoding method provided by the present application. The group of decoded frames are decoding results of the encoded frames by using the decoding method provided by the present application.

205, the encoding device derives a context information of a target frame according to the reconstructed global semantics and the prediction information by using a context extraction model.

In some embodiments, the context information of the target frame may include N piece(s) of scale information.

When N=1, that is, the context information includes only one piece of scale information, the scale information is an output of the context extraction model.

When Nis a positive integer greater than one, then N pieces of scale information are in one-to-one correspondence with N layers of the context extraction model. In other words, the context extraction model include at least N layers.

206, the encoding device derives a latent representation of the target frame according to the context information by using a signal encoding model.

In some embodiment, before deriving the latent representation of the target frame, the encoding device may further obtain a feature of the target frame. Then the encoding device may derives the latent representation of the target frame from the feature of the target frame according to the context information by using the signal encoding model.

When the context information of the target frame include one piece of scale information, the scale information and the target frame may be input together into the signal encoding model.

When the context information of the target frame include more than one piece of scale information, the N pieces of scale information may be in one-to-one correspondence with N layers of the signal encoding model, and each of the N pieces of scale information may be as an input of a corresponding layer of the signal encoding model.

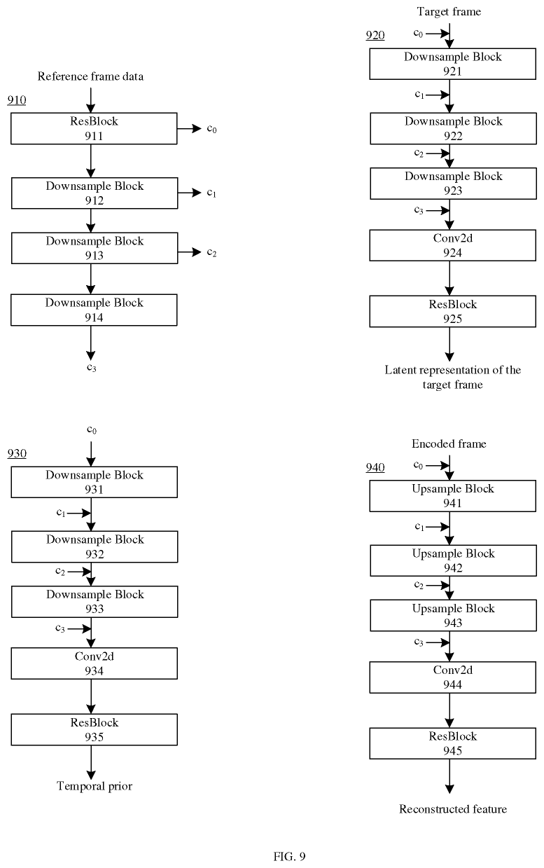

FIG. 9 illustrates a context extraction model and a signal encoding model.

Referring to FIG. 9, the context extraction model 910 includes a ResBlock 911, a downsample block 912, a downsample block 913, and a downsample block 914. The signal encoding model 920 includes a downsample block 921, a downsample block 922, a downsample block 923, a Conv2d layer 924, and a ResBlock 925.

In some embodiments, the architecture of the downsample blocks illustrated in FIG. 9 may be the same as the global encoding model 700, and the architecture of the ResBlocks illustrated in FIG. 9 may be the same as the ResBlock 710.

Referring to FIG. 9, the context extraction model 910 may output four pieces of scale information, that is, c₀, c₁, c₂, and c₃ illustrated in FIG. 9. Referring to FIG. 9, the scale information c₀ and the target frame are both input into the downsample block 921, while a first layer of the downsample block 921 is a layer corresponding to the scale information c₀. Similarly, the scale information c₁ and an output of the downsample block 921 are both input into the downsample block 922, the scale information c₂ and an output of the downsample block 922 are both input into the downsample block 923, and the scale information c₃ and an output the downsample block 923 are both input into the Conv2d layer 924. A size of the scale information is the same as a size of the output that is input into the corresponding layer together with the scale information. For example, a size of the scale information c₀ is the same as a size of the target frame, a size of the scale information is the same as a size of the output of the downsample block 921, and so on.

207, the encoding device performs an entropy coding operation on the latent representation of the target frame to obtain an encoded target frame.

In some embodiment, the entropy coding operation may be an arithmetic coding, a context-based adaptive variable length coding, a context-adaptive binary arithmetic coding, or the like.

In some embodiment, the encoding device may derive a temporary prior information, and the encoding device may perform the entropy coding operation on the latent representation of the target frame according to the temporary prior information to obtain the encoded target frame. The temporary prior information refers to prior knowledge about a time-dependent behavior of frames. The temporary prior information may include motion vectors between frames, time-correlated pixel predictions, or the like. The temporary prior information may be used to improve efficiency and compression performance of the entropy coding. In some embodiments, the encoding device may derive the temporary prior information by using a temporary prior model. The temporary prior model may include at least N layers, where each of the N piece(s) of the scale information corresponds to one layer of the temporary prior model, and the each of the N piece(s) of the scale information is an input of the corresponding layer of the temporary prior model.

Referring to FIG. 9, FIG. 9 illustrates a temporary prior model 930. The temporary prior model 930 includes a downsample block 931, a downsample block 932, a downsample block 933, a Conv2d layer 934, and a ResBlock 935. As illustrated in FIG. 9, the scale information c₀ is an input of the downsample block 931. In other words, a first layer of the downsample block 931 is a layer corresponding to the scale information c₀, and the scale information c₀ is an input of the first layer of the downsample block 931. Similarly, the scale information c₁ is an input of the downsample block 932, and an output of the downsample block 931 is input into the downsample block 932 along with the scale information c₁. The scale information c₂ is an input of the downsample block 933, and an output of the downsample block 932 is input into the downsample block 933 along with the scale information c₂. The scale information c₃ is an input of the Conv2d layer 934, and an output of the downsample block 933 is input into the Conv2d layer 934 along with the scale information c₃. Similarly, the size of the scale information is the same as a size of data that is input into the corresponding layer together with the scale information. For example, the size of the scale information c₁ is the same as the output of the downsample block 931.

In some embodiments, the encoding method may further include step 208.

208, the encoding device transmit the encoded target frame and the encoded global feature corresponding to the global semantics to a decoding device.

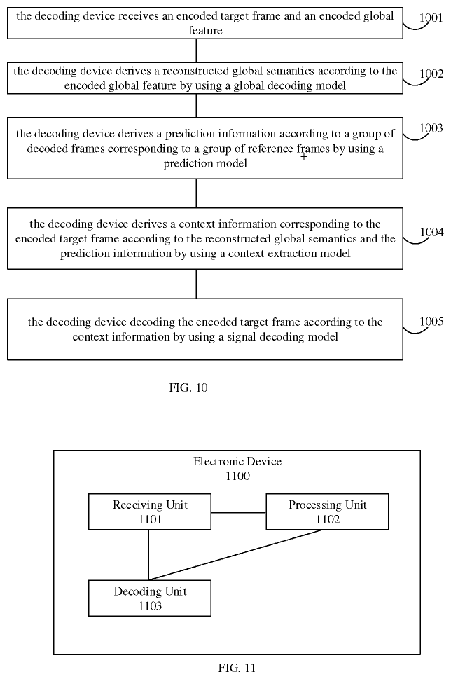

FIG. 10 illustrates a decoding method according to some embodiments of the present application. For convenience, it is assumed that the operation illustrated in FIG. 10 is performed by a decoder or an decoding device. In some embodiments, the decoder or the decoding device may be a terminal device (e.g., a personal computer, a laptop, a mobile phone, a tablet computer, an augmented reality (AR)/virtual reality (VR) terminal, or the like), a server, a network device or the like. In some other embodiments, the decoder or the decoding device may be a component in the terminal, the server, the network device or the like. For example, the decoder or the decoding device may be a chip, a system on chip (SoC), a circuit, and so on.

1001, the decoding device receives an encoded target frame and an encoded global feature.

The encoded target frame and the encoded global feature are transmitted by the encoding device in step 208. In other words, the encoded target frame is an encoding result of the target frame by using the encoding method illustrated by FIG. 2.

1002, the decoding device derives a reconstructed global semantics according to the encoded global feature by using a global decoding model.

A method for deriving the reconstructed global semantics by the decoding device is the same as a method for deriving the reconstructed global semantics by the encoding device. For example, the global decoding model used by the encoding device (hereinafter referred to as the first global decoding model) is the same as the global decoding model used by the decoding device (hereinafter referred to as the second global decoding model). Therefore, when an input of the first global decoding model is the same as an input of the second global decoding model, an output of the first global decoding model is the same as an output of the second global decoding model. For specific details on how to determining the reconstructed global semantics, please refer to the above-mentioned embodiments, which will not be reiterated here. In other words, the reconstructed global semantics used by the decoding device for decoding the encoded target frame is the same as the reconstructed global semantics used by the encoding device for encoding the target frame.

1003, the decoding device derives a prediction information according to a group of decoded frames corresponding to a group of reference frames by using a prediction model.

The group of decoded frames corresponds to a group of encoded frames obtained by the group of reference frames by using the encoding method provided by the present application. The group of decoded frames are decoding results of the encoded frames by using the decoding method provided by the present application.

Similarly, a method for deriving the prediction information by the decoding device is the same as a method for deriving the prediction information by the encoding device. For example, the prediction model used by the encoding device (hereinafter referred to as the first prediction model) is the same as the prediction model used by the decoding device (hereinafter referred to as the second prediction model). Therefore, when an input of the first prediction model is the same as an input of the second prediction model, an output of the first prediction model is the same as an output of the second prediction model. For specific details on how to determining the prediction information, please refer to the above-mentioned embodiments, which will not be reiterated here. In other words, the prediction information used by the decoding device for decoding the encoded target frame is the same as the prediction information used by the encoding device for encoding the target frame.

1004, the decoding device derives a context information corresponding to the encoded target frame according to the reconstructed global semantics and the prediction information by using a context extraction model.

The context extraction model used by the decoding device for obtaining the context information (hereinafter referred to as a second context extraction model) may be the same as the context extraction model used by the encoding device for obtaining the context information during a procedure that is used to encode the target frame (hereinafter referred to as a first context extraction. Therefore, when an input of the first context extraction model is the same as an input of the second context extraction model, an output of the context extraction model is the same as an output of the context extraction model. In other words, the context information obtained by step 1004 is the same as the context information obtained by step 205.

1005, the decoding device decoding the encoded target frame according to the context information by using a signal decoding model.

As previously mentioned, in some embodiments, the context information obtained by the encoding device may include one or more pieces of scale information. Similarly, the context information obtained by the decoding device may also include one or more pieces of scale information. When the context information obtained by the decoding device includes N piece(s) of scale information, the signal decoding model may include at least N layer(s), where each of the N piece(s) of scale information is an input of one of the at least N layer(s), Nis a positive integer.

FIG. 9 illustrates a signal decoding model. Referring to FIG. 9, the signal decoding model 940 includes an upsample block 941, an upsample block 942, an upsample block 943, a Conv2d layer 944, and a ResBlock 945. The scale information c₃ and the encoded target frame are both input to the upsample block 941. The upsample block 941 may include several layers, and the scale information c₃ and the encoded target frame are an input of the first layer among the several layers. Similarly, the scale information c₂ and an output of the upsample block 941 are both input into the upsample block 942, the scale information c₁ and an output of the upsample block 942 are both input into the upsample block 943, and the scale information c₀ and an output of the upsample block 943 are both input into the Conv2d layer 944.

In some embodiments, the output of the signal decoding model 940 may be a reconstructed feature of the target frame. Under this condition, the decoding device may further derives a reconstructed target signal according to the reconstructed feature of the target frame by using a signal generating model.

Table 4 illustrates models used in the encoding method and the decoding method provided by the present application.

TABLE 4

| | |
|---|---|
| 1 | global extraction model |
| 2 | global decoding model |
| 3 | prediction model |
| 4 | context extraction model |
| 5 | signal encoding model |
| 6 | global encoding model |
| 7 | temporary prior model |
| 8 | signal decoding model |
| 9 | signal generating model |

As previously mentioned, the global extraction model may be achieved by one of the following networks: the neural network with 3D convolutional layer, the U-net convolution network, or the transformer. Similar to the global extraction model, all models illustrated in Table 4 may be achieved by one of the above-mentioned networks, a CNN, a DNN, or the like.

In some embodiments, some of the models illustrated in Table 4 may be trained together. For example, the global extraction model, the global decoding model, the prediction model, the context extraction model, the global encoding model, the temporary prior model.

In some embodiments, the global decoding model and the global encoding model may be trained together.

In some embodiments, the signal encoding model, the temporary prior model, the signal decoding model a,d the signal generating model may be trained together.

In some embodiments, the global extraction model, the global decoding model, and the global encoding model may be trained together.

In some embodiments, the global extraction model and the context extraction model may be trained together.

In some embodiments, the context extraction model, the signal encoding model, the temporary prior model, the signal decoding model, and the signal generating model may be trained together.

In some embodiment, one or more of the above-mentioned models may include several sub-models or sub-network. One or more of the sub-networks may be trained independently or pretrained. For example, in some embodiments, the prediction model may be achieved by using a deep contextual video compression-diverse contexts (DCVC-DC) model and an alphaVC mode. Take the DCVC-DC model as an example, the DCVC-DC model may be trained using 4 different stages: training of motion vector (MV) Autoencoder, training with distortion only, training p-frame model with RD-loss and freezed MV Autoencoder, finetuning the whole model with RD-loss. Training of MV Autoencoder is important and independent on the other part of the model, a pretrained MV Autoencoder may be used.

In some embodiments, all of the models illustrated in Table 4 may be trained together.

In some embodiments, models of the embodiments provided by the present application may be trained with rate-distortion loss (RD-loss):

L=λ·D+R
where D is a distortion and R is a bitrate cost and lambda controls trade-off between those two terms. The distortion may be mean squared error, multi-scale structural similarity index, or the like.

In some other embodiments, models of the embodiments provided by the present application may be trained based mean absolute error (MAE), structural similarity index (SSIM), video quality metric (VQM) or the like.

FIG. 11 is a schematic block diagram of an electronic device 1100 according to some embodiments of the present application. The electronic device 1100 may be the aforementioned decoding device. Referring to FIG. 11, the electronic device 1100 includes a receiving unit 1101, a processing unit 1102, and a decoding unit 1103.

The receiving unit 1101 may be configured to receive an encoded signal and an encoded global feature.

The processing unit 1102 may be configured to derive a reconstructed global semantics according to the encoded global feature by using a global decoding model.

The processing unit 1102 may be further configured to derive a predication information according to a series of decoded signals by using a prediction model.

The processing unit 1102 may be further configured to derive a context information corresponding to the encoded signal according to the reconstructed global semantics and the prediction information according to a context extraction model.

The decoding unit 1103 may be configured to decode the encoded signal according to the context information by using a signal decoding model.

The processing unit 1102 and the decoding unit 1103 may be implemented by a processor. In some embodiments, the processing unit 1102 and the decoding unit 11031104 may be implemented by the one processor. In some other embodiments, the processing unit 1102 and the decoding unit 1103 may be implemented by different processors. In some embodiments, the receiving unit 1101 may be implemented by a receiver or a receiving circuit of the processor.

Details on how to decode the encoded signal may refer to the above-mentioned embodiments and will not be described here.

FIG. 12 is a schematic block diagram of an electronic device 1200 according to some embodiments of the present application. The electronic device 1200 may be the aforementioned encoding device. Referring to FIG. 12, the electronic device 1200 includes a processing unit 1201, a decoding unit 1202, and an encoding unit 1203.

The processing unit 1201 may be configured to derive a global semantics of a series of input signals by using a global extraction model.

The processing unit 1201 may be further configured to derive an encoded global feature corresponding to the global semantics.

The decoding unit 1202 may be configured to decode the encoded global feature corresponding to the global semantics to obtain a reconstructed global semantics by using a global decoding model.

The processing unit 1201 may be further configured to derive a prediction information according to a series of decoded signals corresponding to the series of input signals by using a prediction model.

The processing unit 1201 may be further configured to derive a context information of the target input signal according to the reconstructed global semantics and the prediction information by using a context extraction model.

The processing unit 1201 may be further configured to derive a latent representation of the target input signal according to the context information by using a signal encoding model.

The encoding unit 1203 may be configured to perform an entropy coding operation on the latent representation of the target input signal to obtain an encoded signal.

In some embodiments, the electronic device may further include a transmitting unit 1204. The transmitting unit 1204 may be configured to transmit the encoded signal and the encoded global feature corresponding to the global semantics.

The processing unit 1201, the decoding unit 1202, and the encoding unit 1203 may be implemented by a processor. In some embodiments, the processing unit 1201, the decoding unit 1202, and the encoding unit 1203 may be implemented by the one processor. In some other embodiments, the processing unit 1201, the decoding unit 1202, and the encoding unit 1203 may be implemented by two or more processors. The transmitting unit 1204 may be implemented by a transmitter or a transmitting circuit of the processor.

Details on how to encode the target input signal may refer to the above-mentioned embodiments and will not be described here.

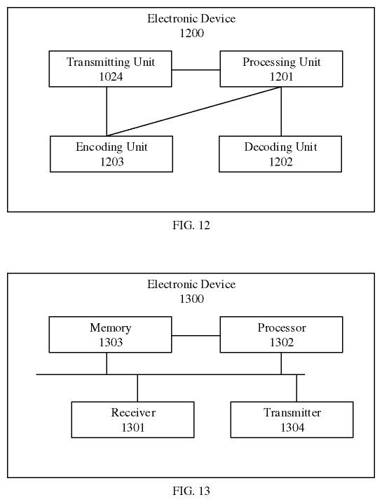

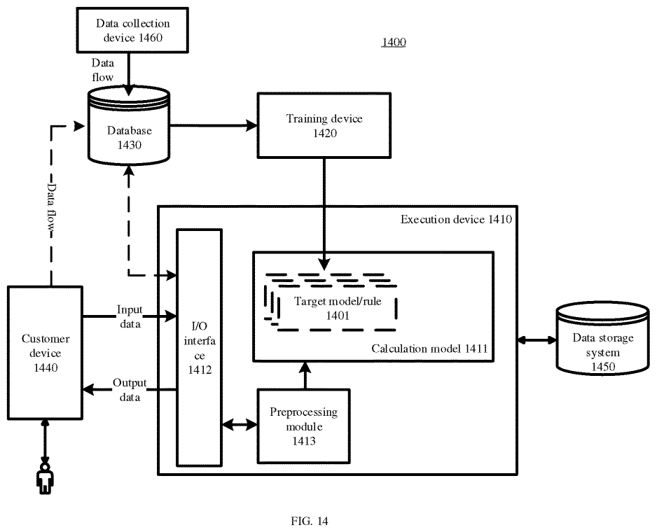

As shown in FIG. 13, an electronic device 1300 may include a receiver 1301, a processor 1302, a memory 1303, and a transmitter 1304. The memory 1303 may be configured to store code, instructions, and the like executed by the processor 1302.

It should be understood that the processor 1302 may be an integrated circuit chip and has a signal processing capability. In an implementation process, steps of the foregoing method embodiments may be completed by using a hardware integrated logic circuit in the processor, or by using instructions in a form of software. The processor may be a general purpose processor, a central processing unit (CPU), a graphics processing unit (GPU), a neural processing unit (NPU), a system on chip (SoC) or another programmable logic device, a discrete gate or transistor logic device, or a discrete hardware component. The processor may implement or perform the methods, the steps, and the logical block diagrams that are disclosed in the embodiments of the present application. The general purpose processor may be a microprocessor, or the processor may be any conventional processor or the like. The steps of the methods disclosed with reference to the embodiments of the present application may be directly performed and completed by the processor, or may be performed and completed by using a combination of hardware in the processor and a software module. The software module may be located in a mature storage medium in the art, such as a random access memory, a flash memory, a read-only memory, a programmable read-only memory, an electrically erasable programmable memory, or a register. The storage medium is located in the memory, and the processor reads information in the memory and completes the steps of the foregoing methods performed by the encoding device or the decoding device in combination with hardware in the processor.

It may be understood that the memory 1303 in the embodiments of the present application may be a volatile memory or a nonvolatile memory, or may include both a volatile memory and a nonvolatile memory. The nonvolatile memory may be a read-only memory (Read-Only Memory, ROM), a programmable read-only memory (Programmable ROM, PROM), an erasable programmable read-only memory (Erasable PROM, EPROM), an electrically erasable programmable read-only memory (Electrically EPROM, EEPROM), or a flash memory. The volatile memory may be a random access memory (Random Access Memory, RAM) and is used as an external cache. By way of example rather than limitation, many forms of RAMs may be used, and are, for example, a static random access memory (Static RAM, SRAM), a dynamic random access memory (Dynamic RAM, DRAM), a synchronous dynamic random access memory (Synchronous DRAM, SDRAM), a double data rate synchronous dynamic random access memory (Double Data Rate SDRAM, DDR SDRAM), an enhanced synchronous dynamic random access memory (Enhanced SDRAM, ESDRAM), a synchronous link dynamic random access memory (Synchronous link DRAM, SLDRAM), and a direct rambus random access memory (Direct Rambus RAM, DR RAM).

It should be noted that the memory in the electronic device and the methods described in this specification includes but is not limited to these memories and a memory of any other appropriate type.

Referring to FIG. 14, an embodiment of the present application provides a system architecture 1500. As shown in the system architecture 1400, a data collection device 1460 is configured to collect training data. The training data may be stored into a database 1430. A training device 1420 may obtain at least one target model/rule 1401 through training based on the training data maintained in the database 1430. Each of the at least one target model/rule 101 may be corresponding to one of the aforementioned models The at least one target model/rule 1401 in this embodiment of this application may specifically be a neural network, a convolution network or the like to obtained through training. In this embodiment provided in this application, the network is obtained by training an initialized network. It should be noted that, in actual application, the training data maintained in the database 1430 is not necessarily all collected by the data collection device 1460, and may be received from another device. In addition, it should be noted that the training device 1420 does not necessarily perform training completely based on the training data maintained in the database 1430 to obtain the at least one target model/rule 1401, and may obtain training data from a cloud or another place to perform model training. The foregoing description shall not be construed as a limitation on this embodiment of this application.

The at least one target model/rule 1401 obtained by the training device 1420 through training may be applied to different systems or devices, for example, applied to an execution device 1410 shown in FIG. 14. The execution device 1410 may be a terminal, such as a mobile phone terminal, a tablet computer, a notebook computer, an augmented reality (AR) device, a virtual reality (VR) device, or a vehicle-mounted terminal, or may be a server or the like. In FIG. 14, an I/O interface 1412 is configured on the execution device 1410 and is configured to exchange data with an external device. A user may input data into the I/O interface 1412 by using a customer device 1440. The input data may be data collected by the execution device 1410 by using the data collection device 1460, may be data in the database 1430, or may be data from the customer device 1440. The input data may be an image, a video frame, an audio data, a text data or the like, and the present application is not limited thereto.

A preprocessing module 1413 is configured to perform preprocessing based on the input data (for example, the input image) received by the I/O interface 1412. For example, the preprocessing module 1413 may be configured to implement one or more of the following operations: flipping, rotation, scaling, grayscale conversion, demozaicking, color correction, lens shading correction, auto white balance and the like; and is further configured to implement another preprocessing operation. This is not limited in this application.

In a related processing procedure in which the execution device 1410 preprocesses the input data or a calculation module 1411 of the execution device 1410 performs calculation, the execution device 1410 may invoke data, code, and the like in a data storage system 1450 to implement corresponding processing, and may also store, into the data storage system 1450, data, an instruction, and the like obtained through corresponding processing.

Finally, the I/O interface 1412 returns a processing result, for example, the foregoing obtained image processing result, to the customer device 1440, to provide the processing result for the user.

As previously mentioned, in some embodiments, the training device 1420 may obtain, through training based on the same training data, a part of or all of the at least one target model/rule 1401 together. The corresponding target models/rules 1401 may be used to implement the foregoing targets or complete the foregoing tasks, to provide a required result for the user.

In a case shown in FIG. 14, the user may manually provide the input data. The manually providing may be performed by using a screen provided on the I/O interface 1412. In another case, the customer device 1440 may automatically send the input data to the I/O interface 1412. If it is required that the customer device 1440 needs to obtain authorization from the user to automatically send the input data, the user may set corresponding permission on the customer device 1440. The user may view, on the customer device 1440, a result output by the execution device 1410. Specifically, the result may be displayed or may be presented in a form of sound, an action, or the like. The customer device 1440 may also be used as a data collection end to collect the input data that is input into the I/O interface 1412 and an output result that is output from the I/O interface 1412, as shown in the figure, use the input data and the output result as new sample data, and store the new sample data into the database 1430. Certainly, alternatively, the customer device 1440 may not perform collection, and the I/O interface 1412 directly stores, into the database 1430 as new sample data, the input data that is input into the I/O interface 1412 and an output result that is output from the I/O interface 1412, as shown in the figure.

It should be noted that FIG. 14 is merely a schematic diagram of a system architecture provided in an embodiment of the present application. A location relationship between a device, a component, a module, and the like shown in the figure constitutes no limitation. For example, in FIG. 14, the data storage system 1450 is an external memory relative to the execution device 1410. In another case, the data storage system 1450 may be alternatively disposed in the execution device 1410. In this application, the target model/rule 1401 obtained through training based on the training data may be a neural network used for performing the aforementioned encoding/decoding operation.

The present application provides a computer readable storage medium including instructions. When the instructions run on an electronic device, the electronic device is enabled to perform the aforementioned method.

The present application provides a computer readable storage medium. The computer readable storage medium stores the bitstream obtained by the aforementioned method.

The present application provides a chip system. The chip system includes a memory and a processor, and the memory is configured to store a computer program, and the processor is configured to invoke the computer program from the memory and run the computer program, so that an electronic device on which the chip system is disposed performs the aforementioned method.

The present application provides a computer program product. When the computer program product runs on an electronic device, the electronic device is enabled to perform the aforementioned method.

In the embodiments of the present application, “at least one” means one or more, and “a plurality of” means two or more. The term “and/or” describes an association relationship between associated objects and represents that three relationships may exist. For example, A and/or B may represent the following three cases: only A exists, both A and B exist, and only B exists, where A and B may be singular or plural. The character “/” generally indicates an “or” relationship between the associated objects. “At least one of the following” and a similar expression thereof refer to any combination of these items, including any combination of one item or a plurality of items. For example, at least one of a, b, and c may indicate: a, b, c, a and b, a and c, b and c, or a, b, and c, where a, b, and c may be singular or plural.

A person of ordinary skill in the art may be aware that, in combination with the examples described in the embodiments disclosed in this specification, units and algorithm steps can be implemented by electronic hardware or a combination of computer software and electronic hardware. Whether the functions are performed by hardware or software depends on particular applications and design constraints of the technical solutions. A person skilled in the art may use different methods to implement the described functions for each particular application, but it should not be considered that the implementation goes beyond the scope of this application.

It may be clearly understood by a person skilled in the art that, for the purpose of convenient and brief description, for a detailed working process of the foregoing system, apparatus, and unit, refer to a corresponding process in the foregoing method embodiment. Details are not described herein again.

In the several embodiments provided in this application, it should be understood that the disclosed system, apparatus, and method may be implemented in other manners. For example, the described apparatus embodiment is merely an example. For example, the unit division is merely logical function division and may be other division in actual implementation. For example, a plurality of units or components may be combined or integrated into another system, or some features may be ignored or not performed. In addition, the displayed or discussed mutual couplings or direct couplings or communication connections may be implemented through some interfaces. The indirect couplings or communication connections between the apparatuses or units may be implemented in electronic, mechanical, or other forms.

The units described as separate parts may be or may not be physically separate, and parts displayed as units may be or may not be physical units, may be located in one position, or may be distributed on a plurality of network units. Some or all of the units may be selected based on actual requirements to achieve the objectives of the solutions of the embodiments.

In addition, functional units in the embodiments of this application may be integrated into one processing unit, or each of the units may exist alone physically, or two or more units are integrated into one unit.

When the functions are implemented in a form of a software functional unit and sold or used as an independent product, the functions may be stored in a computer readable storage medium. Based on such an understanding, the technical solutions in this application essentially, or the part contributing to the prior art, or some of the technical solutions may be implemented in a form of a software product. The computer software product is stored in a storage medium, and includes several instructions for instructing a computer device (which may be a personal computer, a server, a network device, or the like) to perform all or some of the steps of the methods described in the embodiments of this application. The foregoing storage medium includes: any medium that can store program code, such as a USB flash drive, a removable hard disk, a read-only memory (Read-Only Memory, ROM), a random access memory (Random Access Memory, RAM), a magnetic disk, or an optical disc.

The foregoing descriptions are merely specific implementations of this application, but are not intended to limit the protection scope of this application. Any variation or replacement readily figured out by a person skilled in the art within the technical scope disclosed in this application shall fall within the protection scope of this application. Therefore, the protection scope of this application shall be subject to the protection scope of the claims.

What is claimed is:

1. A decoding method, wherein comprising:
receiving an encoded signal and an encoded global feature;
deriving a reconstructed global semantics according to the encoded global feature by using a global decoding model;
deriving a predication information according to a series of decoded signals by using a prediction model;
deriving a context information corresponding to the encoded signal according to the reconstructed global semantics and the prediction information by using a context extraction model;
decoding the encoded signal according to the context information by using a signal decoding model.

2. The method according to claim 1, wherein the context information comprises N piece(s) of scale information, N is a positive integer;
the decoding the encoded signal according to the context information by using a signal decoding model, comprises:
decoding the encoded signal according to the N piece(s) of scale information by using the signal decoding model, wherein the signal decoding model comprises at least N layer(s), each of the N piece(s) of scale information is an input of one of the at least N layer(s).

3. The method according to claim 1, wherein the decoding the encode signal according to the context information by using a signal decoding model, comprises:
decoding the encoded signal according to the context information to obtain a reconstructed feature of a target signal by using the signal decoding model;
the method further comprises:
deriving a reconstructed target signal according to the reconstructed feature of the target signal by using a signal generating model.

4. An encoding method, wherein comprising:
deriving a global semantics of a series of input signals by using a global extraction model;
deriving an encoded global feature corresponding to the global semantics;
decoding the encoded global feature corresponding to the global semantics to obtain a reconstructed global semantics by using a global decoding model;
deriving a prediction information according to a series of decoded signals corresponding to the series of input signals by using a prediction model;
deriving a context information of the target input signal according to the reconstructed global semantics and the prediction information by using a context extraction model;
deriving a latent representation of the target input signal according to the context information by using a signal encoding model;
performing an entropy coding operation on the latent representation of the target input signal to obtain an encoded signal.

5. The method according to claim 4, wherein the deriving an encoded global feature corresponding to the global semantic, comprises:
deriving a global latent representation of the global semantics by using a global encoding model;
performing the entropy coding operation on the global latent representation of the global semantics to obtain the encoded global feature corresponding to the global semantic.

6. The method according to claim 4, wherein the deriving a global semantics of a series of input signals by using a global extraction model, comprises:
extracting the global semantics of the series of input signals from the series of input signals by using the global extraction model.

7. The method according to claim 4, wherein the deriving a global semantics of a series of input signals by using a global extraction model, comprises:
deriving a latent representation of the series of input signals;
extracting the global semantics of the series of input signals from the latent representation of the series of input signals by using the global extraction model.

8. The method according to claim 4, wherein the deriving a global semantics of a series of input signals by using a global extraction model, comprises:
deriving motion information of the series of input signals;
extracting the global semantics of the series of input signals from the motion information of the series of input signals by using the global extraction model.

9. The method according to claim 4, wherein the context information of the target input signal comprises N piece(s) of scale information, N is a positive integer;
the deriving a latent representation of the target input signal according to the context information by using a signal encoding model, comprises:
deriving a latent representation of the target input signal according to the N piece(s) of scale information by using the signal encoding model, wherein the signal encoding model comprises at least N layer(s), each of the N piece(s) of scale information is an input of one of the at least N layer(s).

10. The method according to claim 8, wherein the method further comprises:
deriving a temporal prior information according to the N piece(s) of scale information by using a temporal prior model, wherein the temporal prior model comprises at least N layer(s), each of the N piece(s) of scale information is an input of one of the at least N layer(s);
the performing an entropy coding operation on the latent representation of the target input signal to obtain an encoded signal, comprises:
performing the entropy coding operation on the latent representation of the target input signal according to the temporal prior information to obtain the encoded signal.

11. The method according to claim 4, wherein the method further comprises:
transmitting the encoded signal and the encoded global feature corresponding to the global semantics.

12. An electronic device, comprising:
one or more processors; and
a memory operatively coupled to the one or more processors and configured to store computer readable instructions that, when executed by the one or more processors, cause the electronic device to:
derive a global semantics of a series of input signals by using a global extraction model;
derive an encoded global feature corresponding to the global semantics;
decode the encoded global feature corresponding to the global semantics to obtain a reconstructed global semantics by using a global decoding model;
derive a prediction information according to a series of decoded signals corresponding to the series of input signals by using a prediction model;
derive a context information of the target input signal according to the reconstructed global semantics and the prediction information by using a context extraction model;
derive a latent representation of the target input signal according to the context information by using a signal encoding model;
perform an entropy coding operation on the latent representation of the target input signal to obtain an encoded signal.

13. The electronic device according to claim 12, wherein the electronic device is further caused to:
derive a global latent representation of the global semantics by using a global encoding model;
perform the entropy coding operation on the global latent representation of the global semantics to obtain the encoded global feature corresponding to the global semantic.

14. The electronic device according to claim 12, wherein the electronic device is further caused to:
extract the global semantics of the series of input signals from the series of input signals by using the global extraction model.

15. The electronic device according to claim 12, wherein the electronic device is further caused to:
derive a latent representation of the series of input signals;
extract the global semantics of the series of input signals from the latent representation of the series of input signals by using the global extraction model.

16. The electronic device according to claim 12, wherein the electronic device is further caused to:
derive motion information of the series of input signals;
extract the global semantics of the series of input signals from the motion information of the series of input signals by using the global extraction model.

17. The electronic device according to claim 12, wherein the context information of the target input signal comprises N piece(s) of scale information, N is a positive integer;
wherein the electronic device is further caused to:
derive a latent representation of the target input signal according to the N piece(s) of scale information by using the signal encoding model, wherein the signal encoding model comprises at least N layer(s), each of the N piece(s) of scale information is an input of one of the at least N layer(s).

18. The electronic device according to claim 16, wherein the electronic device is further caused to:
derive a temporal prior information according to the N piece(s) of scale information by using a temporal prior model, wherein the temporal prior model comprises at least N layer(s), each of the N piece(s) of scale information is an input of one of the at least N layer(s);
perform the entropy coding operation on the latent representation of the target input signal according to the temporal prior information to obtain the encoded signal.

19. The electronic device according to claim 12, wherein the electronic device is further caused to:
transmit the encoded signal and the encoded global feature corresponding to the global semantics.
